(19) United States
(12) Patent Application Publication
(10) Pub. No.: US 2010/0078803 A1
(43) Pub. Date: Apr. 1, 2010

(54) SEMICONDUCTOR FLAT PACKAGE DEVICE AND METHOD FOR MANUFACTURING THE SAME

(75) Inventors: HIDEKO ANDOU, KANAGAWA (JP); TOSHINORI KIYOHARA, KANAGAWA (JP)

Correspondence Address: YOUNG & THOMPSON, 209 Madison Street, Suite 500, Alexandria, VA, 22314, US

(73) Assignee: NEC ELECTRONICS CORPORATION, KANAGAWA (JP)

(21) Appl. No.: 12/569,085

(22) Filed: Sep. 29, 2009

(30) Foreign Application Priority Data
Sep. 30, 2008 (JP) 2008-253633

(51) Int. Cl. H01L 23/48; H01L 21/50

(52) U.S. Cl. 257/693; 438/124; 257/E21.499; 257/E23.01

(57) ABSTRACT

A semiconductor flat package device capable of attaining a favorable operation and ensuring a sufficient spreading quality of solder for the lead top end is provided. A semiconductor chip 1 is encapsulated by an encapsulation resin. At first, a lead is half-blanked on the side of the top end of the lead protruding from the encapsulation region in the direction from the soldering surface to the printed circuit board, thereby forming a half-blanked region. Then, a plating layer is formed to the half-blanked region of the lead. Then, the lead is cut from the upper end of the half-blanked region formed with the plating layer in the direction from the soldering surface. The half-blanked region and the lead cut region form the top end face of the lead which forms a pseudo-planar face. Thus, a plating layer of a sufficient area is formed stably to the top end face of the lead. As a result, a solder fillet of a sufficient height is formed stably at the top end face of the lead.

### CROSS-REFERENCE TO RELATED APPLICATIONS

This application is based upon, claims the benefit of priority of, and incorporates by reference the contents of Japanese Patent Application No. 2008-253633 filed on Sep. 30, 2008.

### BACKGROUND

Along with the demand for decreasing the mounting area of packages, packages having flat type leads such as SOF (Small OutlineFlat-leaded) packages have been increased in recent years. Means for completely covering the lead top end of this package by plating includes, for example, a method of applying electrolytic plating to a structure in which adjacent tie bars are disposed for connecting leads on lateral sides to each other and lead top ends are previously cut, and then cutting the adjacent tie bars. However, the size of the adjacent tie bars that can be disposed is restricted and this method is difficult to be adopted as the thickness of the lead frame increases. In a case of a package having a large thickness for the lead frame, a manufacturing process of cutting leads after plating is used generally at present. In this case, the plating layer is rolled-up upon lead cutting and the plating layer is deposited to a portion of the lead cut surface. However, the range for depositing the plating layer is narrow and control for the plating area is difficult.

Further, in the recent trend of decreasing the size of semiconductor packages, the area of the lead for mechanical and electrical connection with a printed circuit board has been decreased more and more. Particularly, in the SOF, the length of the lead protruding out of the encapsulation resin portion of the package is about 0.15 to 0.5 mm and the plating layer is formed substantially completely over the entire upper and lower surfaces of the lead. However, the lead top end is generally cut after plating and while the plating layer is deposited partially to the cutting surface at the lead top end, a base material of the lead is exposed for most of the surface. The area of the plating layer rolled up and deposited to the cutting surface of the lead top end changes depending on the controlled state upon lead cutting and/or the extent of abrasion of the punching die and it is difficult to ensure a predetermined area. That is, it is difficult to stably ensure the spreading quality of the solder at the lead top end.

In a case where the solder spreading quality at the lead top end is poor, a solder fillet is not formed and the solder is spread only at the bottom of the lead. Accordingly, this makes it difficult for the judgment of the spreading quality upon visual inspection of the solder after soldering to a printed circuit board. The height of the solder fillet is important for inspection, particularly, by an automatic visual inspection apparatus and it is desirable that the height of the solder fillet is one-half or more for the thickness of the lead for stable judgment. Also in the visual inspection with naked eyes, the judgment is facilitated when the height of the solder fillet is one-half or more for the lead thickness.

Under the situations described above, various manufacturers have devoted themselves to the provision of a plating method and the structure or construction method for enduring the spreading quality of solder to the lead top end. For example, Japanese Unexamined Patent Application Publication (JP-A) No. 2005-209999 (first patent document) discloses a semiconductor device of improving the depositability of the solder to a portion of the lead top end. A method of manufacturing a semiconductor device described in the first patent document is to be described briefly.

At first, a lead top end is bent upward or downward by a half-blanking method and plating is applied subsequently. Upon lead cutting, since the lead is cut at a position leaving the bent portion, a step is formed at the top end of the lead. According to the method, an area to be covered with the plating layer can be increased by forming the step to the lead top end thereby capable of improving the spreading quality of solder more compared with a case where the step is not present at the lead top end.

However, in a case of the semiconductor device described in the first patent document, the solder is situated below the step and made invisible as viewed from above and it is difficult to be recognized upon inspection of the spreading quality of solder with naked eyes or by an automatic visual inspection apparatus in the production line. Particularly, in the automatic visual inspection apparatus, while the height of the solder fillet formed at the cutting surface of the lead top end is important, since only the plating layer that is rolled-up and deposited is formed at the cutting surface of the lead top end by the method of the first patent document, the height and the stability of the solder fillet are insufficient. Accordingly, the solder fillet cannot be sometimes detected by the automatic visual inspection apparatus making it difficult for stable inspection.

Further, in Japanese Unexamined Patent Application Publication (JP-A) No. 5-291456 (second patent document), the lead top end is plated by forming a concave portion to the lead top end. Specifically, a step is formed to the lead top end and the lead is cut on the side of the top end near the step. In this case, a die is abutted against the surface of the package at a position on the side of the base of the lead from the cut line and the lead is cut by a punch from the rear face of the package at a position on the side of the lead top end from the step.

However, it has been revealed by the inventors' verification that the technique described in the second patent document involves a problem that a lead portion protruding on the side of the package surface is crushed due to the step by the die upon cutting. That is, the lead top end is widened laterally. This may possibly cause short-circuit between adjacent leads or lowering of voltage withstanding.

Further, the second patent document discloses an example of forming a V-shaped groove instead of the step. This is to be described with reference to FIG. 11A and FIG. 11B. FIG. 11A is a fragmentary cross sectional view of a lead 113 formed with a V-shaped groove 114. FIG. 11B is a fragmentary cross sectional view showing the state of bonding by soldering the lead 113 cut in the midway of the V-shaped groove 114 to the printed circuit board. In the state shown in FIG. 11A, a plating layer (not illustrated) is formed to the top end of the lead 113 and then the lead 113 is cut in the midway of the V-shaped groove 114. Accordingly, a plating layer (not illustrated) is formed in the V-shaped groove 114 and a solder fillet 117a is formed at the lead top end at a height larger than that in the usual case. A similar technique is also disclosed in U.S. Pat. No. 6,392,293 B2 (third patent document).

However, it has been found by the inventor's verification that the following problem occurs. The problem is to be described with reference to FIG. 12A and FIG. 12B. FIG. 12A is a fragmentary cross sectional view in a state of driving a blade 115 into a lead 113 for forming a V-shaped groove 114. FIG. 12B is a fragmentary cross sectional view of an actual lead 113 formed with the V-shaped groove 114. Upon forming the groove 114, since the blade 115 drives the lead member outward of the groove 114, it raises like a bank 116 at the outward of the groove 114. Particularly, as the groove 114 is deeper, the height of the bank 116 increases to worsen the planarity at the connection surface with the printed circuit board. Accordingly, connection with the printed circuit board becomes sometimes insufficient. The height of the bank 116 changes depending on the depth of the groove 114, the angle of the groove 114, and the angle of applying the blade 115 upon forming the groove 114. Accordingly, it is difficult to control the height of the bank 116.

### SUMMARY

The present invention provides, in one aspect, a method of manufacturing a semiconductor flat package device of encapsulating a semiconductor chip with an encapsulation resin. The method includes half-blanking a lead to form a half-blanked region at which a top end face of the lead is to be formed. The half-blanked region is half-blanked in the direction from a soldering surface of the lead. The soldering surface is formed on a lower end of the lead. Further, the method includes forming a plating layer in the half-blanked region, and cutting a partially connecting portion of the lead adjacent to the half-blanked region to form a lead cut region. The direction of the cutting a partially connecting portion of the lead is the same direction as that of the half-blanking a lead. The half-blanked region and the lead cut region form the top end face of the lead which has a pseudo-planar face.

The present invention provides, in another aspect according to the invention, a semiconductor flat package device includes a semiconductor chip encapsulated by an encapsulation resin. A lead electrically connected with the semiconductor chip protrudes from the encapsulation resin. A half-blanked region is formed at a top end face of the lead and includes a sheared surface. A lead cut region is disposed from an upper end of the half-blanked region to an upper end of the top end face of the lead and includes a fractured surface. A plating layer is formed in the half-blanked region at the top end face of the lead. The half-blanked region and the lead cut region form the top end face of the lead which has a pseudo-planar face.

Specifically, the half-blanked region includes a sheared surface of 50% or more for the lead thickness. The plating layer is formed to the half-blanked region. The lead is fractured at the upper end of the half-blanked region to form the lead cut region, so that the fractured surface of the lead cut region is to be formed a pseudo-planar face with the sheared surface of the half-blanked region. A height of a solder fillet can be 50% or more for the lead thickness, and the solder fillet can be inspected easily.

Therefore, the present invention can provide a semiconductor flat package device capable of attaining favorable operation and ensuring a sufficient spreading quality of solder at the top end of the lead.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1A is a schematic side elevational view of a semiconductor flat package device according to Embodiment 1;

FIG. 1B is a front elevational view of a semiconductor flat package device shown in FIG. 1A;

FIG. 2A is a fragmentary enlarged cross sectional view near the lead of the semiconductor flat package device shown in FIG. 1A;

FIG. 2B is an enlarged cross sectional view for the top end of the lead shown in FIG. 2A;

FIG. 2C is an enlarged front elevational view for top end of the lead shown in FIG. 2A;

FIG. 3A and FIG. 3B are, respectively, fragmentary cross sectional views near a lead of a conventional semiconductor flat package device soldered above a printed circuit board in a comparative example;

FIG. 4A to FIG. 4C, and FIG. 5A to FIG. 5B are fragmentary cross sectional views showing a method of manufacturing a semiconductor flat package device according to Embodiment 1;

FIGS. 6A to 6B and FIGS. 7A to 7B are fragmentary cross sectional views showing a method of manufacturing a conventional semiconductor flat package device in the comparative example shown in FIG. 3B;

FIG. 8 is an enlarged front elevational view for the top end face of the lead according to Embodiment 2;

FIGS. 9A to 9D and FIGS. 10A and 10B are, respectively, fragmentary upper plan views and fragmentary side elevational views showing a method of manufacturing the semiconductor flat package device according to Embodiment 2;

FIG. 11A is a fragmentary cross sectional view of an existent lead formed with a V-shaped groove;

FIG. 11B is a fragmentary cross sectional view showing a state where the lead cut in the midway of the existent V-shaped groove is soldered to a printed circuit substrate;

FIG. 12A is a fragmentary cross sectional view that explains the problem in a state of driving a blade into the lead for forming the V-shaped groove; and

FIG. 12B is a fragmentary cross sectional view that explains the problem in an actual lead formed with the V-shaped groove.

### DETAILED DESCRIPTION OF THE PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

### Embodiment 1

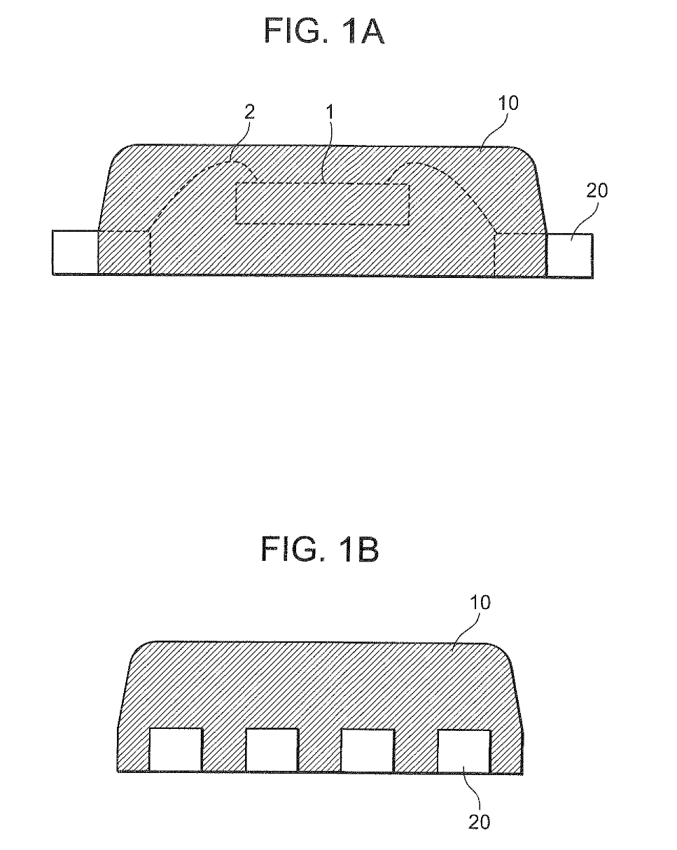

At first, with reference to FIG. 1A and FIG. 1B, a semiconductor flat package device according to Embodiment 1 of the invention is to be described. FIG. 1A is a schematic side elevational view showing the constitution of a semiconductor flat package device. FIG. 1B is a front elevational view of the semiconductor flat package device. An SOF (Small Outline Flat-leaded) package is to be described herein as an example of the semiconductor flat package device. In the SOF package, flat shape leads are led out from two lateral sides of a rectangular encapsulation resin.

The semiconductor flat package device includes a semiconductor chip 1, an encapsulation resin 10, and leads 20. The encapsulation region 10 encapsulates the semiconductor chip 1 thereby protecting the semiconductor chip against the external circumstance. The semiconductor chip 1 at mounted on a not illustrated die pad. The leads 20 are formed to the outer edge of the encapsulation resin 10. The leads 20 are connected electrically with the semiconductor chip 1 and protrude from the encapsulation resin 10. That is, the leads 20 can be connected from the outside. The leads 20 extend from the two opposing sides of the encapsulation resin 10. The leads 20 extend from the inside of the encapsulation resin 10. Further, the semiconductor chip 1 and the lead 20 are electrically connected by bonding wires 2 in the inside of the encapsulation resin 10.

The leads 20 are formed in plurality on respective lateral sides and are in parallel with each other. In FIG. 1B, leads 20 are formed by the number of 4 on one lateral side and are in parallel with each other. Further, each of the leads 20 has substantial constant width and thickness from the base (on the side of the encapsulation resin 10) to the top end (on the side opposite to the encapsulation resin 10). Accordingly, short-circuit or lowering of the voltage withstanding less occurs between the adjacent leads 20.

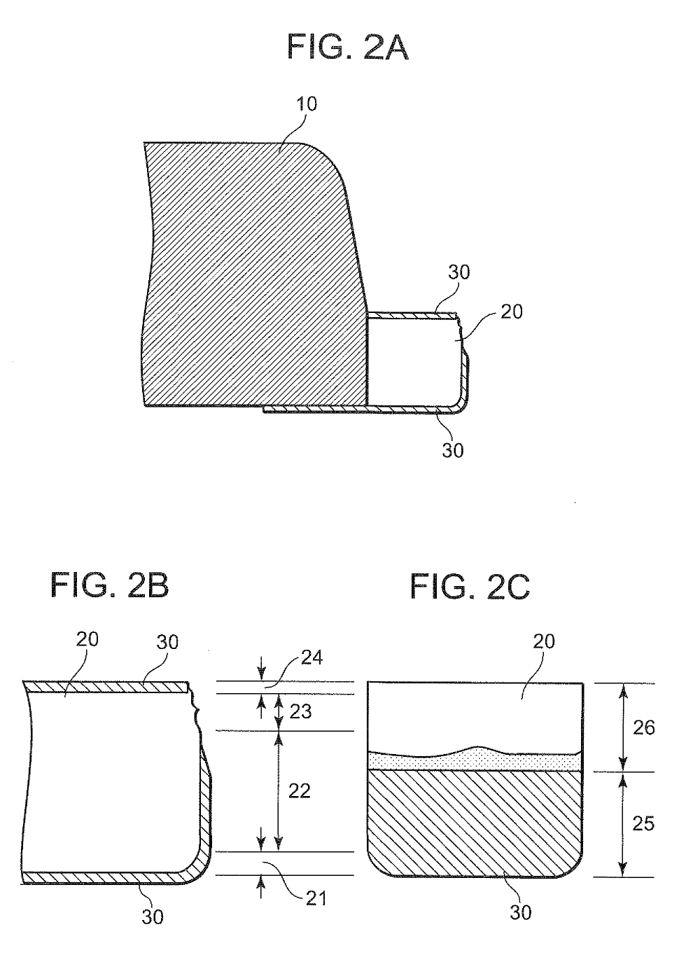

Then, a detailed structure for the portion of the lead 20 is to be described with reference to FIGS. 2A to 2C. FIG. 2A is a fragmentary enlarged cross sectional view near the lead 20. FIG. 2B is an enlarged cross sectional view at the top end of the lead 20 and FIG. 2C is an enlarged front elevational view thereof.

As shown in FIG. 2A, a plating layer 30 is formed substantially entirely over the upper surface and the lower surface of the lead 20. The plating layer 30 is formed substantially over the entire top end face of the lead 20 excepting for the upper portion. Although not illustrated in FIGS. 2A to 2C, the plating layer 30 is formed also on the lateral sides of the lead 20 substantially over entire surface. That is, the lead 20 that protrudes from the encapsulation resin 10 is covered with the plating layer 30 except for the upper portion on the top end face of the lead 20.

The lead 20 is formed by lead cutting after half-blanking. Half-blanking means fabrication of pressing a member placed on a die by a punch thereby putting the member into a half-cut state. That is, the lead 20 has a partially connecting portion which is not completely cut by half-blanking.

Usually, when the lead 20 is cut, a shear droop 21, a sheared surface 22, a fractured surface 23, and cut burrs 24 are formed on the cut surface of the lead 20 as shown in FIG. 2B. At the top end face of the lead 20, the shear droop 21, the sheared 22, the fractured surface 23, and the cut burrs 24 are formed successively from the rear side of the package. The fractured surface 23 occupies a region of about 20% for the lead thickness. During cutting of the lead 20 by the punch, fine cracks are formed in the region which will become the fractured surface 23 after the lead 20 is completely cut. Accordingly, in the region of the fractured surface 23, punch cutting does not occur but fracture occurs along the fine cracks. That is, the fractured surface 23 is formed by fracture along the fine cracks. In this case, the rear face of the package is the side of the soldering surface connected to the printed circuit board in the semiconductor flat package device. Further, the shear droop 21, the sheared surface 22, the fractured surface 23, and the cutting burrs 24 extend substantially vertically from the bottom of the lead 20 on the side of the rear face of the package. That is, steps, indents, etc. are scarcely formed at the top end face of the lead 20. In other words, the top end face of the lead 20, which includes the shear droop 21, the sheared surface 22, the fractured surface 23 and the cutting burrs 24, forms a pseudo-planar face.

At the top end face of the lead 20, a half-blanked region 25 formed by half-blanking and a lead cut region 26 cut by lead cutting are successively formed from the rear side of the package. The upper end of the half-blanked region 25 and the lower end of the lead cut 26 are aligned, and the lead cut region 26 is formed from the upper end of the half-blanked region 25 to the upper end of the top end face of the lead 20. Further, cutting burrs 24 are formed on the upper portion of the lead cut region 26 that extends in the direction from the rear face of the package to the surface of the package. The half-blanking amount, that is, the half-blanked region 25 occupies a region of 50 to 80% from the rear face of the package at the top end face of the lead 20. That is, at the top end face of the lead 20, the half-blanked region 25 is formed in a region of 50 to 80% for the lead thickness from the lower end.

The lower limit of the half-blanking amount is defined as 50% in order to ensure the height of a solder fillet by at least one-half or more for the lead thickness upon soldering to the printed circuit board. Further, in order to retain the half-blanked position within the sheared surface 22, the upper limit is defined as 80%. Fine cracks are present in the fractured region and the fine cracks may possibly be communicated to each other even by small impact. In a case where the half-blanking position exceeds the sheared surface 22 and the lead is connected only in the region of the fractured surface, fine cracks in the fractured surface may be communicated by vibrations due to deflashing after the half-blanking step or in the plating step to possibly cut the lead 20. The half-blanking position is the end of the half-blanked region 25 on the side of the lead cut region 26. That is, the half-blanking position is the upper end of the half-blanked region 25.

The half-blanked region 25 corresponds to a region from the lower end of the shear droop 21 to the midway in the direction of the height for the sheared surface 22. That is, the half-blanked region 25 has the shear droop 21 and the sheared surface 22. The lead cut region 26 corresponds to a region from a midway in the direction of the height of the shared surface 22 to the upper end of the cut burrs 24. That is, the lead cut region 26 has the sheared surface 22, the fractured surface 23, and the cutting burrs 24. Further, at the top end face of the lead 20, a plating layer 30 is formed from the lower end of the half-blanked region 25 to a midway in the direction of the height for the lead cut region 26. That is, the plating layer 30 is formed from the lower end of the shear droop 21 to a midway in the direction of the height for the sheared surface 22. Specifically, the plating surface 30 is formed substantially over the entire surface of the half-blanked region 25. Further, the plating layer 30 is formed to a portion of the lead cut region 26 on the side of the lower end. In FIG. 2C, the plating layer 30 in the half-blanked region 25 is indicated thickly and the plating layer 30 in the lead cut region 26 is indicated thinly. The semiconductor flat package device is constituted as has been described above.

In the semiconductor flat package device according to this embodiment, the half-blanked region 25 occupies a region from 50 to 80% for the lead thickness from the rear side of the package at the top end face of the lead 20. That is, at the top end face of the lead 20, the plating layer 30 covers a region of 50% or more for the lead thickness from the lower end. Then, upon soldering to the printed circuit substrate, a solder 41 prevails by spreading to the plating layer 30.

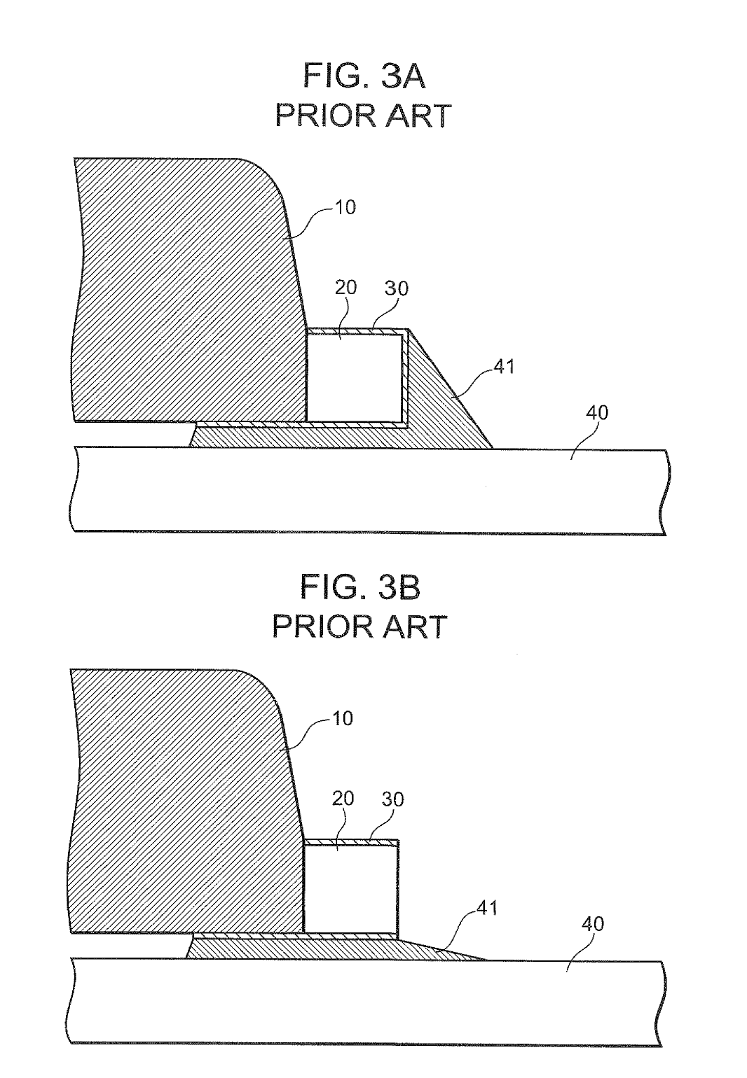

The height of the solder fillet upon soldering to the printed circuit board is to be described with reference to a comparative example. FIG. 3A and FIG. 3B are, respectively, fragmentary cross sectional views near the lead 20 of a conventional semiconductor flat package device of a comparative example that is soldered to a printed circuit board 40. FIG. 3A shows a comparative example showing a case where the top end face of the lead 20 is covered completely by a plating layer 30. FIG. 3B shows a comparative example showing a case where the top end face of the lead 20 is not covered at all by the plating layer 30.

Conductive patterns (not illustrated) are formed on the printed circuit board 40. The conductive patterns are formed respectively corresponding to a plurality of leads 20 of the semiconductor flat package device. Then, each of the leads 20 and each of the conductive patterns corresponding thereto are connected by means of the solder 41. The solder 41 prevails by spreading to the plating layer 30. Accordingly, in a case where the top end face of the lead 20 is covered completely by the plating layer 30, the solder 41 prevails by spreading to the uppermost end of the lead 20. On the other hand, in a case where the top end face of the lead 20 is not covered at all by the plating layer 30, the solder 41 does not prevail by spreading to the top end of the lead 20 but is spread only at the bottom of the lead 20. This occurs also in a case where the spreading quality of solder at the top end face is deteriorated, for example, by oxidation of the lead 20.

In a case of judging the spreading quality of solder of the lead 20 after connection to the printed circuit board 40, this is often executed by a method of detecting the height for the solder fillet at the top end of the lead by an automatic visual inspection apparatus thereby checking products. As shown in FIG. 3B, in a case where the solder fillet is not present at all at the top end of the lead 20, it is extremely difficult to detect the solder 41 by the automatic visual inspection apparatus. This also occurs in a case where the solder fillet is formed, but the height thereof is less than 50% for the lead thickness. Accordingly, even if the electrical conductivity and the bonding strength between the lead 20 and the conductive pattern are sufficient, the solder spreading only at the bottom of the lead 20 may be judged as defective. Further, it is also difficult to recognize the solder 41 by visual inspection with naked eyes and this may be also judged as defective.

In a case of the semiconductor flat package device according to this embodiment, the height for the plating layer 30 at the top end face of the lead 20 is between the height of the semiconductor fillets shown in FIG. 3A and that in FIG. 3B. Accordingly, the height of the solder fillet after soldering to the printed circuit board is between the height of the solder fillet shown in FIG. 3A and that in FIG. 3B. Further, in this embodiment, a region of at least 50% or more for the lead thickness is covered with the plating layer 30 and sufficient spreading quality of solder can be ensured for the top end of the lead. Accordingly, the height of the semiconductor fillet can be ensured as 50% or more for the lead thickness. This facilitates judgment by the automatic visual inspection apparatus upon inspection for the spreading quality of solder.

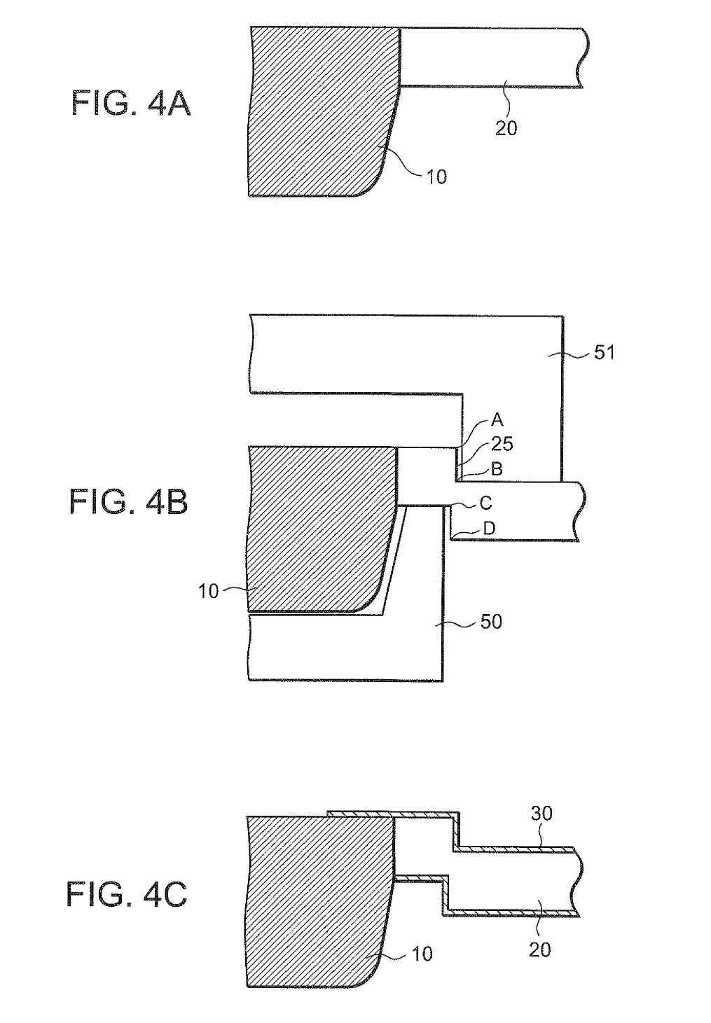

Then, a method of manufacturing a semiconductor flat package device according to this embodiment is to be described. FIGS. 4A to 4C and 5A to 5B are fragmentary cross sectional views showing the method of manufacturing a semiconductor flat package device according to this embodiment.

At first, the semiconductor chip 1 (not illustrated) is mounted above the lead frame and the leads 20 and the semiconductor chip 1 are connected electrically by means of the bonding wires 2 (not illustrated). Then, the semiconductor chip 1 and the bonding wire 2 are encapsulated by the encapsulation resin 10. Patterns for die pads, the leads 20, etc. for mounting the semiconductor chip 1 may be formed to the lead frame. Further, units corresponding to a plurality of semiconductor flat package devices may be formed in an array. By the steps described above, a constitution shown in FIG. 4A is obtained. Then, as shown in FIG. 4B, a half-blanking die 50 is abutted against the lead 20 and half-blanking is executed from the rear side of the package by a half-blanking punch 51 as shown in FIG. 4B. That is, the lead 20 is half-blanked on the side of the top end in the direction opposite to the bonding surface to the printed circuit board. Specifically, a half-blanking die 50 is abutted against the base of the lead 20 from the surface side of the package. Then, the half-blanking punch 51 is abutted against the lead 20 on the side of the top end from the rear side of the package to execute half-blanking.

By the half-blanking, the lead 20 is formed with a step in which a portion corresponding to the top end of a completed lead 20 (lead 20 after lead cutting) is disposed in a convex shape toward the surface of the package. Then, a corner portion A and a corner portion B, each corner portion is substantially at about 90 degree, are formed successively in the direction from the soldering surface of the lead 20 to a portion corresponding to the top end of the completed lead 20. The corner portion A and the corner portion B are formed at positions corresponding to the bottom of the lead 20 before half-blanking. Further, a corner portion C and a corner portion D, each corner portion is substantially at about 90 degree, are also formed successively from the portion corresponding to the top end of the completed lead 20 to the package surface in the direction from the upper surface of the lead 20 to the package surface. The corner portion C and the corner portion D are formed at positions corresponding to the upper surface of the lead 20 before half-blanking. Further, the positions for the corner portions A, B, C, and D are substantially aligned in the longitudinal direction of the lead 20.

A portion between the corner portion A and the corner portion B defines the half-blanked region. That is, a half-blanked region 25 is formed by half-blanking at a position corresponding to the top end of the completed lead 20. As described above, since the half-blanked region 25 as the top end face of the lead 21 is formed, a portion of the region corresponding to the top end face of the completed lead 20 is exposed after half-blanking. That is, the half-blanked region 25 is formed on the side of the bottom at the top end face of the completed lead 20 by half-blanking. Further, the half-blanking amount in this case is defined as a region of 50 to 80% for the lead thickness. That is, the half-blanked region 25 is 50 to 80% for the lead thickness. Since the upper limit is defined as 80%, that is, retained within the sheared surface 22, the connected portion of the lead top end is not cut by vibrations in the step before lead cutting. Further, deflashing and exterior plating are applied. Thus, a plating layer 30 is formed to the surface of the lead 20 including the half-blanked region 25.

As a method of forming the exterior plating layer 30 at about 10 to 20 μm to the lead 20 inexpensively, electrolytic plating is generally applied to a lead frame in a state before it is divided into individual segments. In the electrolytic plating process, a plating metal is deposited on the surface of the lead 20 by attaching electrodes to both ends of the lead frame, dipping them in a plating bath, and supplying electric current. When the top end of the lead 20 is cut completely before plating, electric connection is lost between leads, particularly, the gate lead and the source lead with the main body of the lead frame. Therefore, the plating layer 30 cannot be formed to the separated lead. However, according to the manufacturing method of the invention, plating can be applied in a state of keeping the electric connection between both of the gate lead and the source lead, and the main body of the lead frame. The constitution shown in FIG. 4C is attained by the steps described above.

Subsequently, as shown in FIG. 5A, a die 52 for lead cutting is abutted against the lead 20 and lead cutting is executed from the rear side of the package by a punch 53 for lead cutting. Thus, a lead cut region 26 is formed. Specifically, the die 52 for lead cutting is abutted against the lead 20 on the side of the base in the direction from the surface of the package. The die 52 for lead cutting is abutted against the lead 20 on the side of the base away from the corner portion. Then, the punch 53 for lead cutting is abutted against the top end of the lead 20 in the direction from the rear face of the package to execute lead cutting. Thus, lead cutting is executed at the half-blanking position in the direction from the rear face of the package.

That is, on the side of the package, the upper end portion of the half-blanked region 25 of the lead 20 is cut in the direction from the rear face of the package. As described above, the lead 20 is cut from the top end of the half-blanked region 25 in the direction opposite to the soldering surface. In other words, lead 20 is cut from the corner portion B to the corner portion C. Then, a portion of the sheared surface 22, the fractured surface 23, and the cutting burrs 24 situate at a position from the corner portion B toward the package. As described above, the lead 20 is not cut at a position on the side of the top end ahead of the corner portion B. Therefore, the solder 41 does not become invisible being situated below the step and the spreading quality of solder 41 is inspected easily.

In this case, a portion of the plating metal in the previously formed half-blanked region 25 is rolled up from below to cover the portion of the lead cut region 26 with the plating layer 30. Thus, the plating layer 30 is formed from the lower end of the half-blanked region 25 to the midway in the direction of the height for the lead cut region 26. That is, the plating layer 30 can be deposited also to the top end face of the lead 20 to improve the spreading quality of solder. Further, the plating layer 30 is formed at the top end face of the lead 20 in a region of 50% or more for the lead thickness. With the steps described above, a semiconductor flat package device is manufactured.

The semiconductor flat package device is connected onto the printed circuit board 40. At first, a solder 41 is coated on the conductive patterns (not illustrated) of the printed circuit board 40 respectively. Then, the corresponding lead 20 and solder 41 are connected by reflow process. Thus, the corresponding lead 20 and the conductive pattern are connected by way of the solder 41. Further, in this case, the solder 41 prevails by spreading on the plating layer 30. In this embodiment, the plating layer 30 is formed from the bottom of the lead 20 in a region of 50% or more for the lead thickness. Accordingly, as shown in FIG. 5B, the height of the solder fillet is 50% or more for the lead thickness. That is, H≧T/2, assuming the height for the semiconductor fillet as H and the lead thickness as T. Further, when the package is inspected from the surface, the semiconductor fillet is scarcely concealed by the lead 20. Accordingly, the spreading quality of solder can be inspected easily.

Upon lead cutting, the lead cutting die 52 is abutted against the lead 20 at a position from the corner portion C toward the base. In other words, the lead cutting die 52 is prevented from abutting against the corner portion D. That is, the step of the lead 20 is prevented from being crashed to the rear side of the package. Thus, the top end of the lead 20 is less crashed to adjacent leads 20 and short circuit or lowering of withstand voltage less occurs between the adjacent leads 20. Accordingly, favorable operation can be attained.

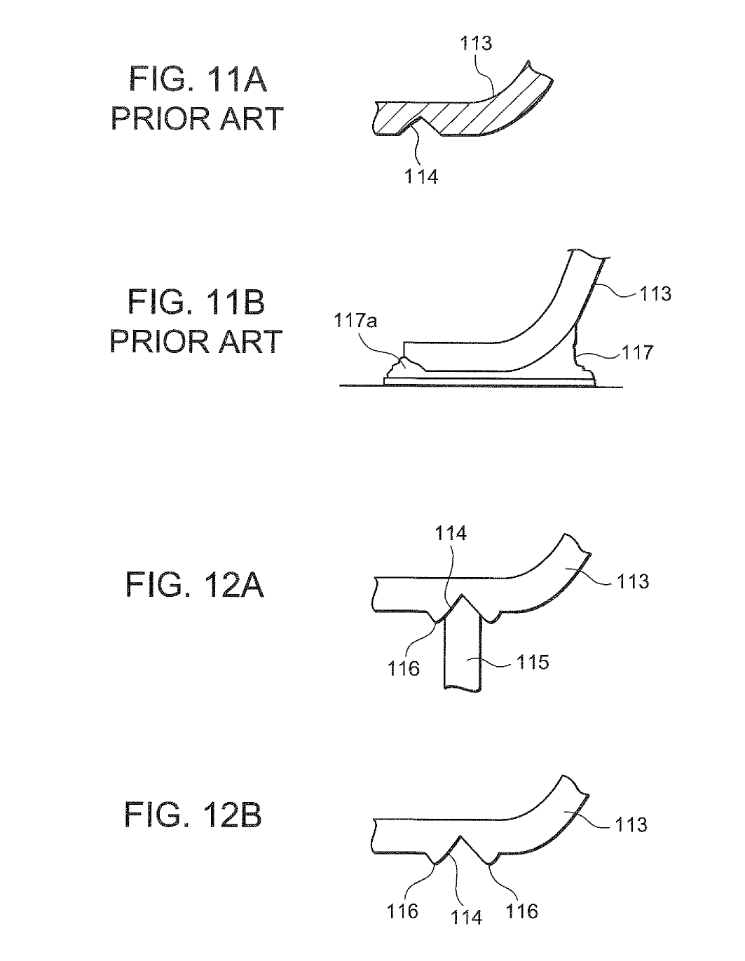

Further, in this embodiment, since the top end face of the lead 20 is exposed by half-blanking before the plating step, raising of the member of the lead 20 in the direction of the soldering surface does not occur. That is, in the existent a case of forming the groove 114 by the blade 115 as shown in FIGS. 12A and 12B, since the blade 115 drives the lead member outward of the groove 114, raising like the bank 116 is formed outward of the groove 114. However, since such distortion is scarcely caused in the half-blanking step of the invention, planarity with the soldering surface can be kept. Then, soldering to the printed circuit board 40 becomes favorable. Further, since the lead length is determined by the step portion formed by half-blanking, the lead length is less varied.

In the manufacturing method described above, while half-blanking for the lead 20 is executed after resin encapsulation, a lead frame previously applied with half-blanking at the lead position may also be used. In this case, the half-blanking step is not necessary in the packaging process for the semiconductor chip and this can save the cost for dies and tools and the operation cost for half-blanking. Also in this case, the half-blanking amount is defined as 50 to 80% for the lead thickness. Further, while the lead 20 is formed into the flat shape in the example described above, the package may be an SOP (Small Outline Package), for example, of a gull wing type having a bent portion. Further, it may be a QFP (Quad Flat Package) in which leads 20 are led out from four lateral sides of the encapsulation resin 10. Any semiconductor flat package device formed with at least one lead 20 can be used.

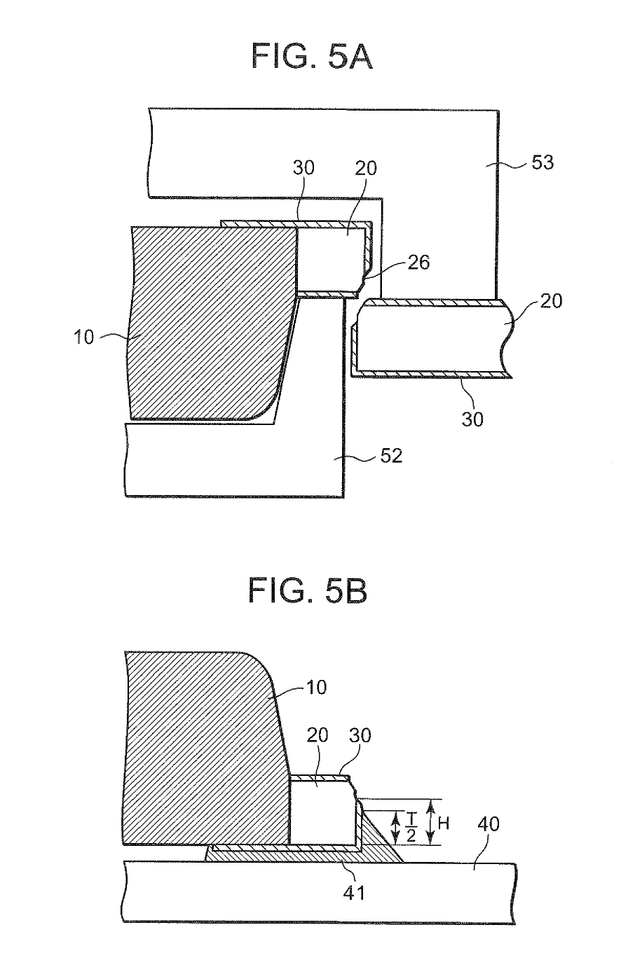

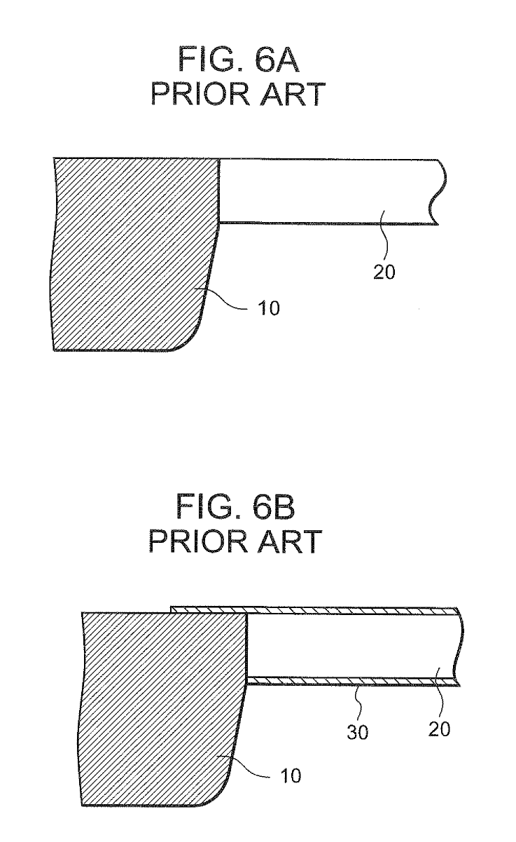

Then, a method of manufacturing the conventional semiconductor flat package device of the comparative example shown in FIG. 3B is to be described with reference to the fragmentary cross sectional views of FIGS. 6A to 6B and 7A to 7B.

In the same manner as in the step shown in FIG. 4A, a semiconductor chip (not illustrated) is mounted above a lead frame, and encapsulated by an encapsulation resin 10. This provides the constitution shown in FIG. 6A. Then, deflashing and exterior plating are applied to provide the constitution shown in FIG. 6B. Subsequently, as shown in FIG. 7A, a lead cutting die 52 is abutted against the lead 20 and lead cutting is executed from the rear side of the package by a punch 53 for lead cutting. With the steps described above, a semiconductor flat package device of the comparative example shown in FIG. 3B is manufactured.

As described above, since lead cutting is executed without half-blanking, a plating layer 30 is not formed to the top end face of the lead 20 and the base material of the lead frame is exposed. While the plating metal rolled up upon lead cutting after plating is sometimes rubbed on the top end face of the lead 20, the roll up amount tends to be changed depending on the cutting condition and/or the abrasion degree of the cutting die. Accordingly, it is difficult to stably cover the area of one-half or more for the lead thickness with the plating layer 30.

In a case of soldering the semiconductor flat package device formed by the step described above to a printed circuit board 40, the height for the solder fillet is lower than one-half for the lead thickness. That is, H<T/2. This is because it is difficult to stably cover the region of one-half or more for the lead thickness from the bottom of the lead 20 by the plating layer 30. Particularly, when the spreading quality of the solder 41 is deteriorated due to oxidation etc. for the lead top end, the solder fillet is not formed at the lead top end as shown in FIG. 3B. That is, unless the plating region at the top end face of the lead 20 occupies one-half or more for the lead thickness from the lower end, also the height of the solder fillet does not reach one-half for the lead thickness. Accordingly, judgment by the automatic visual inspection apparatus becomes difficult upon inspection for the spreading quality of solder.

### Embodiment 2

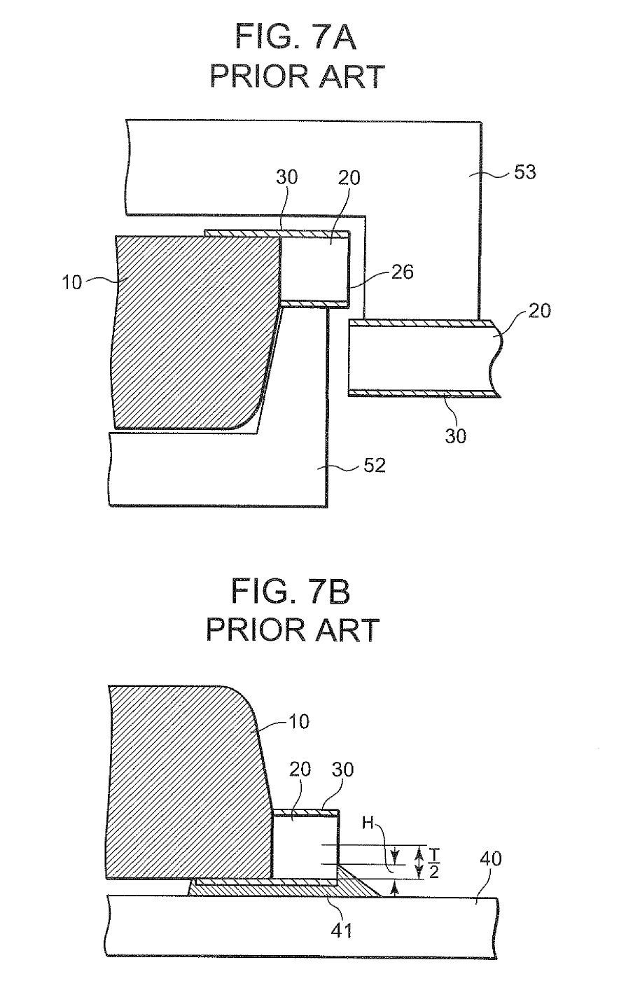

In this embodiment, a plating region formed with a plating layer is present on both lateral ends of the top end face of the lead. Since other constitutions, etc. are in common with those in Embodiment 1, descriptions are to be omitted or simplified. At first, the constitution for the top end face of the lead is to be described with reference to FIG. 8. FIG. 8 is an enlarged front elevational view for the top end face of the lead.

As shown in FIG. 8, a plating region 60 in which a plating layer 30 is formed substantially over the entire region is disposed to both lateral ends at the top end face of the lead 20. The plating region 60 is formed substantially over the entire region of both lateral ends. That is, the plating layer 30 is formed from the lower end to the upper end on both lateral ends at the top end face of the lead 20. Further, the width of the plating region 60 is substantially identical between respective plating regions 60, 60. The total for the width of the two plating regions 60 is about one-half for the width at the top end of the lead 20.

Further, in the lateral central portion at the top end face of the lead 20, a half-blanked region 25 is formed at the lower side end and a lead cut region 26 is formed at the upper side. That is, the half-blanked region 25 and the lead cut region 26 are put between the two plating regions 60. The half-blanked region 25 occupies a 50 to 80% region from the rear side of the package at the top end face of the lead 20. Then, at the top end face of the lead 20, a plating layer 30 is formed about in a central portion from the lower end of the half-blanked region 25 to the midway in the direction of the height for the lead cut region 26 in the same manner as in Embodiment 1. That is, at least a region of 50% or more for the lead thickness is covered by the plating layer 30 about in a central portion of the top end face of the lead 20. In this embodiment, since the plating region 60 is further formed, the plating layer 30 is formed for a region of 75% or more at the top end face of the lead 20.

Also in this embodiment, the same effect as in Embodiment 1 can be obtained. Further, this embodiment has the plating region 60 which is covered by the plating layer 30 substantially over the entire region. Thus, the spreading quality of solder at the top end of the lead 20 is further improved. In this embodiment, while the plating regions 60 are formed on both lateral ends at the top end face of the lead 20, the plating region may be disposed to one of the ends.

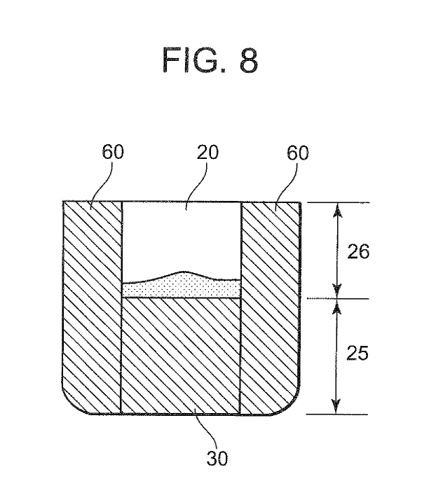

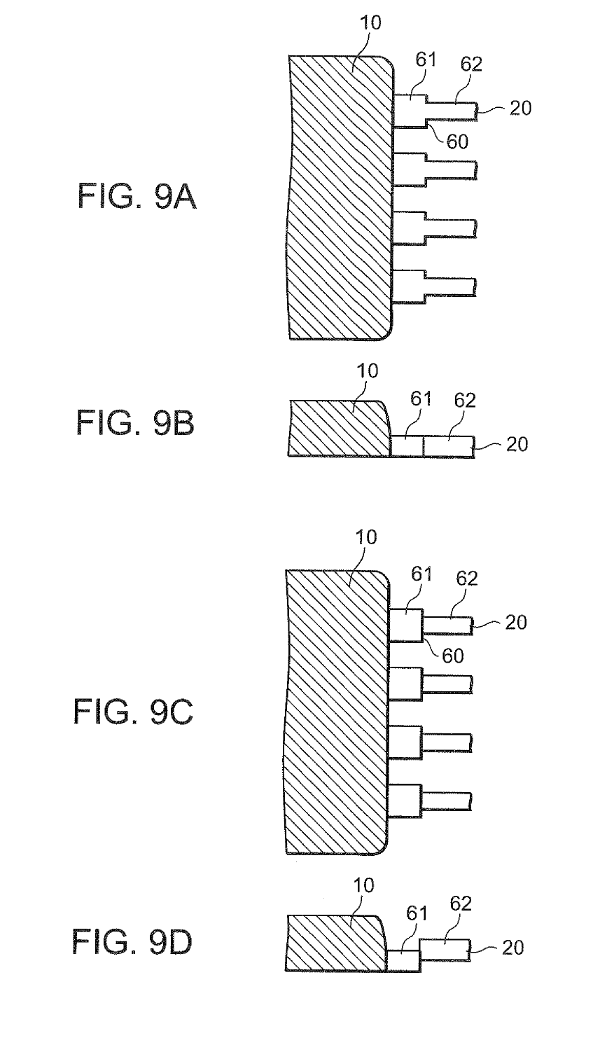

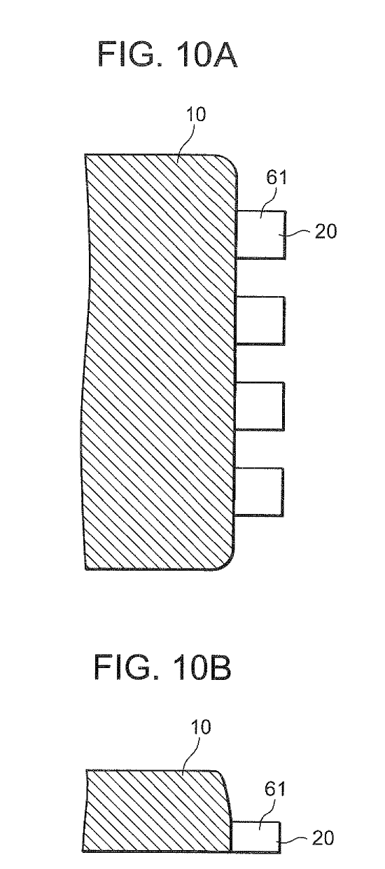

Then, a method of manufacturing a semiconductor flat package device according to this embodiment is to be described with reference to FIGS. 9A to 9D and FIGS. 10A to 10B. FIGS. 9A and 9C and 10A show fragmentary upper plan views near the lead 20 of the semiconductor flat package device in each of the steps. FIGS. 9B, 9D, and 10B are fragmentary side elevational views corresponding to FIGS. 9A, 9C, and 10A, respectively.

At first, the width of the lead 20 is narrowed on the side of the top end. Thus, a wide portion 61 is formed on the side of the base of the lead 20 and a narrow portion 62 is formed on the side of the top end of the lead 20. Further, a plating region 60 is formed at the top end face of the wide portion 61. Specifically, the lead 20 is cut from both lateral ends of the lead 20 each by 25% width. That is, the width for the narrow portion 62 of the lead 20 is about one-half of the wide portion 61 of the lead 20. In this case, with respect to a position corresponding to the top end of the completed lead 20, the wide portion 61 situates on the side of the base and the narrow portion 62 situates on the side of the top end. Further, the lead 20 has a substantially identical thickness both for the wide portion 61 and for the narrow portion 62. The lead 20 described above is formed, for example, by deforming the shape of the lead frame from that of Embodiment 1 before dividing them into individual segments. Then, in the same manner as in Embodiment 1, the semiconductor chip (not illustrated) is mounted above the lead frame and encapsulated by the encapsulation region 10. The constitutions shown in FIGS. 9A and 9B are obtained by the steps described above.

Then, half-blanking is executed in the direction from the rear face of the package. Further, the half-blanking amount in this case is defined as 50 to 80% for the lead thickness in the same manner as in Embodiment 1. Specifically, the vicinity of the boundary between the wide portion 61 and the narrow portion 62 is half-blanked in the direction to the surface of the package. At the top end of the narrow portion 62, the lower end is half-blanked as the corner portion A in Embodiment 1. Thus, only the narrow portion 62 of the lead 20 is punched. Accordingly, a half-blanked region is formed only about the central portion between the lateral ends (plating regions 60) of the lead 20. Further, the plating region 60 and the half-blanked region 25 are contiguous substantially in a planer state. As described above, the plating region 60 and the half-blanked region 25 are exposed. That is, after half-blanking, a portion of a region corresponding to the top end face of the completed lead 20 is exposed. Specifically, in the top end face of the completed lead 20, a region of 75% or more is exposed. The constitution shown in FIGS. 9C and 9D is obtained by the steps described above.

Then, deflashing and exterior plating are applied. This forms the plating layer 30 on the surface of the lead 20 including the plating region 60 and the half-blanked region 25. Subsequently, lead cutting is executed from the half-blanking position. Thus, the lead cut region 26 is formed. The structures shown in FIGS. 10A, 10B, and FIG. 8 are obtained by the steps described above and the semiconductor flat package device of this embodiment is manufactured. In FIGS. 9A to 9D and 10A to 10B, the plating layer 30 is not illustrated. Also by the manufacturing method of the semiconductor flat package device according to this embodiment, the same effects as in Embodiment 1 can be obtained.

Although the invention has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. A method of manufacturing a semiconductor flat package device comprising:
half-blanking a lead to form a half-blanked region at which a top end face of the lead being to be formed, the half-blanked region being half-blanked in the direction from a soldering surface of the lead;
forming a plating layer in the half-blanked region; and
cutting a partially connecting portion of the lead adjacent to the half-blanked region to form a lead cut region, a direction of the cutting a partially connecting portion of the lead being the same direction as that of the half-blanking a lead,
wherein the half-blanked region and the lead cut region form the top end face of the lead which has a pseudo-planar face.

2. The method of manufacturing a semiconductor flat package device according to claim 1, wherein
the half-blanking a lead is executed by half-blanking the lead in a region 50 to 80% for the lead thickness from a lower end at the top end face of the lead.

3. The method of manufacturing a semiconductor flat package device according to claim 1, further comprising:
narrowing the width of the lead on a portion corresponding to the top end face before the half-blanking a lead thereby forming a wide portion on a side of a base of the lead and forming a narrow portion on a side of the top end of the lead,
wherein the half-blanking a lead forms the half-blanked region in a portion in the vicinity of the boundary between the wide portion and the narrow portion.

4. The method of manufacturing a semiconductor flat package device according to claim 3, wherein
the width of the narrow portion is one-half the width of the wide portion.

5. The method of manufacturing a semiconductor flat package device according to claim 1, further comprising:
encapsulating a semiconductor chip by an encapsulation resin,
wherein the lead protrudes from the encapsulation resin, and
wherein the half-blanking a lead executing after the encapsulating a semiconductor chip.

6. The method of manufacturing a semiconductor flat package device according to claim 1, further comprising:
encapsulating a semiconductor chip by an encapsulation resin,
wherein the lead protrudes from the encapsulation resin, and
wherein the encapsulating a semiconductor chip is executed between the forming a plating layer in the half-blanked region and the cutting a partially connecting portion of the lead adjacent to the half-blanked region.

7. A semiconductor flat package device comprising:
a semiconductor chip;
an encapsulation resin that encapsulates the semiconductor chip;
a lead electrically connected with the semiconductor chip and protruding out of the encapsulation resin;
a half-blanked region formed at atop end face of the lead and including a sheared surface;
a lead cut region formed from an upper end of the half-blanked region to an upper end of the top end face of the lead and including a fractured surface; and
a plating layer formed to the half-blanked region at the top end face of the lead,
wherein the half-blanked region and the lead cut region form the top end face of the lead which has a pseudo-planar face.

8. The semiconductor flat package device according to claim 7, wherein
the half-blanked region is formed to a region from 50% to 80% for the lead thickness from a lower end at the top end face of the lead.

9. The semiconductor flat package device according to claim 8, wherein
the plating layer is formed from the lower end to the upper end of at least one of the lateral ends at the top end face of the lead.
